(19) United States
(12) Patent Application Publication
(10) Pub. No.: US 2016/0033992 A1
(43) Pub. Date: Feb. 4, 2016

(54) CASE FOR ELECTRONIC DEVICE INCLUDING A SCREEN

(71) Applicant: BRIGGS & RILEY TRAVELWARE LLC, Hauppauge, NY (US)

(72) Inventor: Marcus Johnsson, Brooklyn, NY (US)

(73) Assignee: BRIGGS & RILEY TRAVELWARE LLC, Hauppauge, NY (US)

(21) Appl. No.: 14/449,752

(22) Filed: Aug. 1, 2014

(51) Int. Cl. G06F 1/16; H05K 5/03

(52) U.S. Cl. CPC G06F 1/1603; H05K 5/03

(57) ABSTRACT

A case for holding an electronic device is disclosed. This case includes a front cover, a rear cover, wherein the front cover and rear cover are operably connected and are configured to form a cavity for placement of an electronic device, the electronic device including a display that is capable of creating a display image, and a filter material that forms at least one portion of the front cover. The filter material provides a diminished image of the display image when the filter material is viewed at an angle between about 5° and about 90°, the angle being horizontally, vertically or a combination of horizontally and vertically from perpendicular to the filter material.

### BACKGROUND OF THE DISCLOSURE

In recent years a great number of electronic devices, such as cell phones, tablet computers, eReaders® and the like have become popular. In particular, such devices are marketed under various trademarks such as Ipad® tablets, Galaxy Tab®, Nook®, Kindle®, and other assorted eReaders® or tablet computers. The use of these devices in public allows for many other people to glance or view the content being viewed by the user while operating the device.

Accordingly, there is a desire for a case for such electronic devices that can act to protect the devices, such as from impacts and environmental conditions, and allow for private viewing of the device during operation. Embodiments of the present disclosure address the above and other issues are discussed herein.

### SUMMARY OF THE DISCLOSURE

The present disclosure includes a case for holding an electronic device. This case includes a front cover, a rear cover, wherein the front cover and rear cover are operably connected and are configured to form a cavity for placement of an electronic device, the electronic device comprising a display that is capable of creating a display image, and a filter material that forms at least one portion of the front cover. The filter material provides a diminished image of the display image when the filter material is viewed at an angle between about 5° and about 90°, the angle being horizontally, vertically or a combination of horizontally and vertically from perpendicular to the filter material.

### BRIEF DESCRIPTION OF THE DRAWINGS

The present disclosure will become better understood with regard to the following description, appended claims, and accompanying drawings wherein:

FIG. 1 is a perspective view of a case for an electronic device according to a first embodiment of the present disclosure;

FIG. 2 is another perspective view of the case of FIG. 1;

FIG. 3 is yet another perspective view of the case of FIG. 1; and

FIG. 4 is a perspective view of a case for an electronic device according to a second embodiment of the present disclosure.

### DETAILED DESCRIPTION OF THE DISCLOSURE

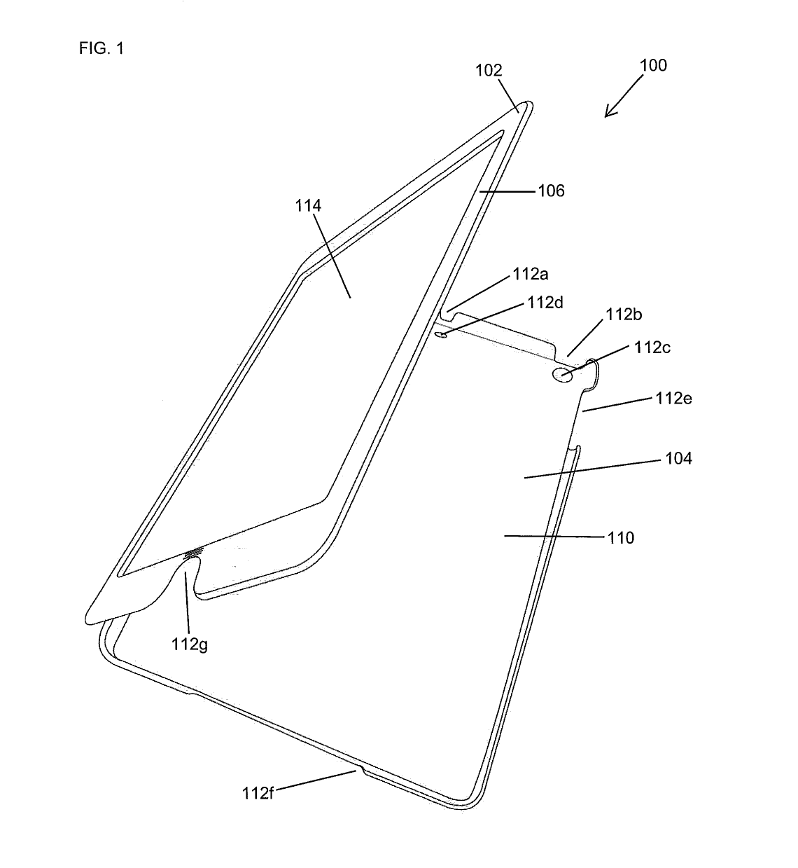

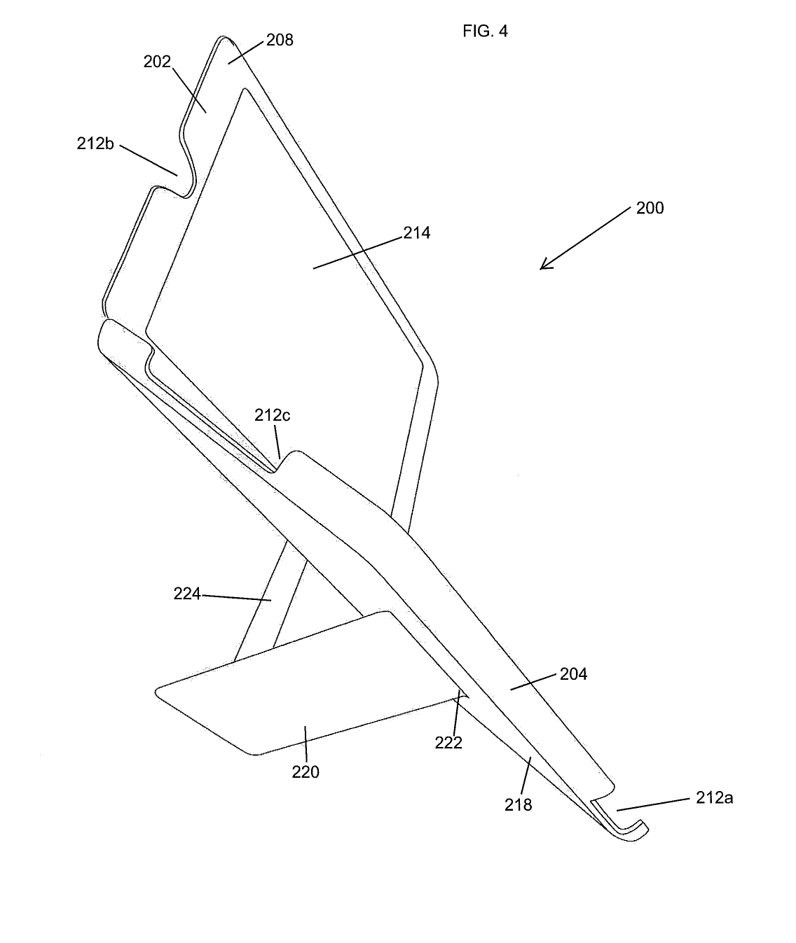

FIGS. 1-3 illustrate a case 100 according to a first embodiment of the present disclosure. FIG. 4 illustrates a case 200 according to a second embodiment of the present disclosure. Cases 100 and 200 can be used for at least one of holding, covering and protecting an electronic device. Although the term “case” will be used throughout the application for the purpose of brevity and consistency, a skilled person understands that other terms can be used equally and interchangeably, such as, protector, cover, enclosure, skin or holder, without departing from the spirit of the present disclosure.

Regarding FIG. 1, the case 100 includes a front cover 102 and a rear cover 104. Front cover 102 and rear cover 104 can be formed of one or more of the same material or one or more of different materials, which can be any suitable material that can maintain a predetermined shape, such as but not limited to, metals, plastics, woods, leathers, vinyls, textile based materials, paper based materials, synthetic and natural rubber materials, foam materials, and other polymers.

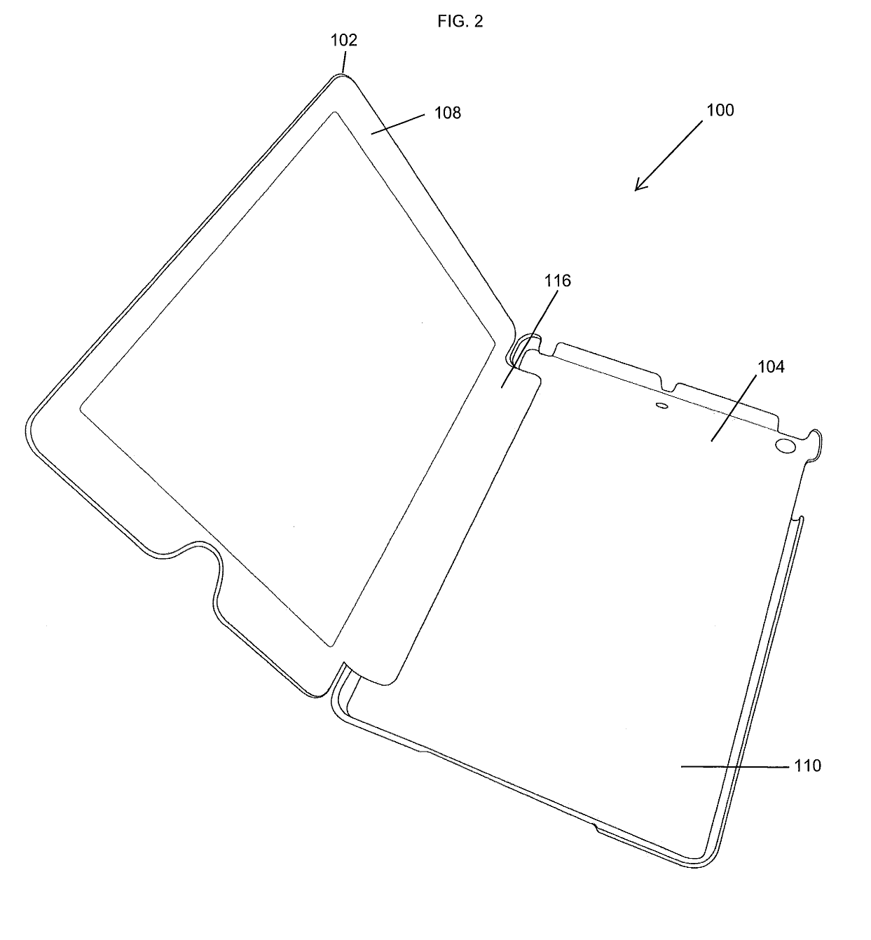

The connection between front cover 102 and rear cover 104 will be shown in FIG. 2 and described when referring to FIG. 2. As can be seen in FIG. 1, the front cover 102 has a front cover exterior face 106 (a front cover interior face is shown in FIG. 2) and the rear cover 104 has a rear cover interior face 110. Front cover 102 and rear cover 104, when in a closed configuration, form a cavity therein, which covers the entirety or a majority of an electronic device placed therein. The shape and dimensions of front cover 102 and rear cover 104 are based on the specific electronic device they are to be used with, and can be modified to be the proper shape and dimension for any portable electronic device.

Both rear cover 104 and front cover 102 can have several openings or access regions where a portion of either the rear cover 104 or front cover 102 is removed. Some non-limiting examples of the placement and size of these openings are shown in FIG. 1 as openings 112a-112g. The size and placement of openings 112a-112g will vary depending on user preference and electronic device type. The openings 112a-112g provide access and operation to various elements of the electronic device, such as, but not limited to, volume control, power control, a camera, a microphone, a headphone access, power inputs or other inputs such as video inputs and speakers. These elements can vary according to specific electronic device and user preference for size and placement of openings.

In other embodiments of case 100, a portion of the material forming the rear cover 104 or front cover 102 can be removed to form openings 112a-112g, such that openings 112a-112g are of a thin enough material to allow for operation and access to various elements of the electronic device.

In another embodiment of case 100, another material, such as a thin plastic sheet for example, can be placed over openings 112a-112g, and adhered or secured to the front cover 102 or the rear cover 104, to cover these openings but still allow for access and operation of the various elements of the electronic device.

Regarding case 100 shown in FIG. 1, at least a portion of front cover 102 includes a filter material 114. Filter material 114 can be a single piece of material, as shown in FIG. 1, or filter material 114 can be multiple pieces of material arranged about front cover exterior face 106 in any suitable pattern or orientation. Filter material 114 can extend over a majority of the front cover exterior face 106, as shown in FIG. 1, or filter material 114 can extend over a smaller portion of front cover exterior face 106.

Case 100 can also include filter material 114 in one or more portions of rear cover 104, so that filter material 114 can cover one or more portions of the rear surface or sides of an electronic device.

In the case 100 of FIG. 1, filter material 114 is configured to extend over the whole display region of an electron device. In other embodiments, filter material 114 can be configured to extend over one or more portions of a display region of an electronic device.

The display region of the electronic device can be any suitable display, including but not limited to, Light Emitting Diode (LED) displays, including but not limited to Organic Light Emitting Diode displays (OLED) and Active-Matrix Organic Light Emitting Diode displays (AMOLED), Liquid Crystal Displays (LCD), Electroluminescent Displays (ELD), electrophoretic displays including electronic paper displays and E ink® displays, Electrowetting Displays (EWD), electrofluidic displays, one or more Plasma Display Panels (PDP), Thin-Film Transistor display (TFT), Surface-conduction Electron-emitter Display (SED), Laser displays, carbon nanotube displays, quantum dot displays, Interferometric Modulator Display (IMOD), Cathode Ray Tube displays (CRT), and combinations of these displays. Each of these can be backlit, can be reflective or can be a combination of backlit and reflective displays.

Filter material 114 can be any suitable material, such as a plastic or glass that is capable of allowing a user to view the display of the electronic device but diminish or exclude the view of other people that are outside a predetermined viewing angle. For example, a user looking straight or perpendicularly through filter material 114 would be able to view the whole image of the display of the electronic device, while another person at a viewing angle of between about 30° and about 90°, horizontally, vertically or a combination of horizontally and vertically from perpendicular to the filter material 114 would see a diminished quality image, such as a darker image, a distorted image, a blurred image, or no image, on the display of the electronic device. In other embodiments, the filter material 114 can be configured to provide a diminished quality image, such as a darker image, a distorted image, a blurred image, or no image, at viewing angles of between about 5° and about 90° , or between about 10° and about 90° , or between about 15° and about 90° , or between about 20° and about 90° , or between about 25° and about 90° , or between about 35° and about 90° , or between about 40° and about 90° , or between about 45° and about 90° , or between about 50° and about 90° , or between about 55° and about 90° , or between about 60° and about 90° , or between about 65° and about 90° , or between about 70° and about 90° , or between about 75° and about 90° , or between about 80° and about 90° , or between about 85° and about 90° horizontally, vertically or a combination of horizontally and vertically from perpendicular to filter material 114.

Some non-limiting examples of suitable filter material 114 are described in U.S. Pat. Nos. 5,528,319, 5,254,388, 7,965,268, and 8,758,882, the contents of which are incorporated by reference. Those of skill in the art will understand that other suitable filter materials 114 can be used, so long as they are capable of allowing a user to view the display of the electronic device but diminish or exclude the view of other people that are outside a predetermined viewing angle.

Referring to FIG. 2, front cover 102 and rear cover 104 are pivotably connected to each other through a first hinge 116, such that the front cover 102 and rear cover 104 can pivot with respect to each other at any desirable angle. First hinge 116 can be any suitable mechanical feature that allows for front cover 102 and rear cover 104 to pivot in relation to each other. First hinge 116 can be formed of one or more materials that can maintain a predetermined shape, such as but not limited to, metals, plastics, woods, leathers, vinyls, textile based materials, paper based materials, synthetic and natural rubber materials, foam materials, and other polymers.

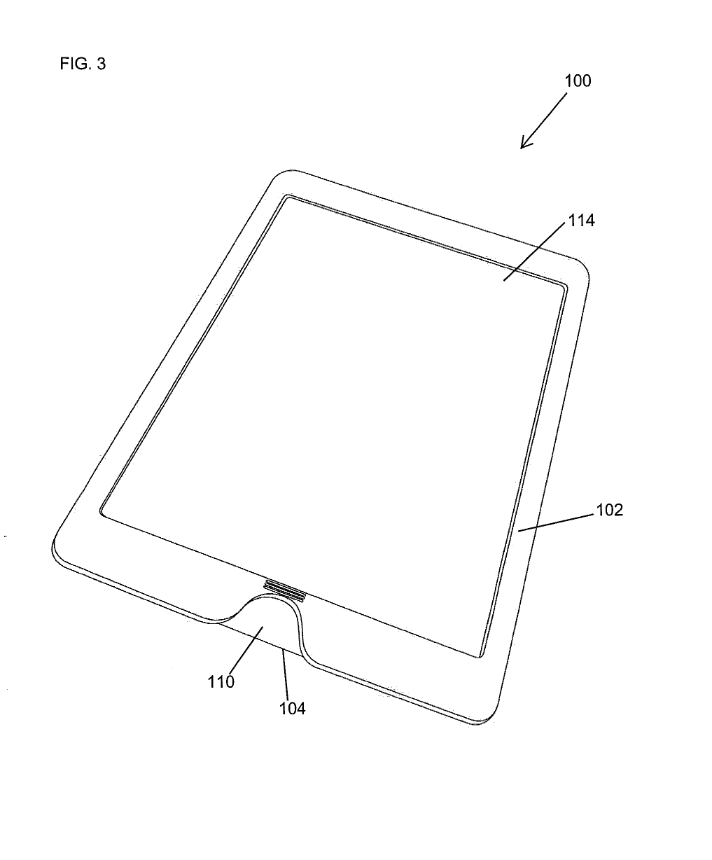

For example, front cover 102 and rear cover 104 can pivot with respect to each other to allow a front cover interior face 108 and the rear cover interior face 110 to approach each other, thereby defining a space in which an electronic device can be accommodated and enclosed by the case 100. This configuration is shown in FIG. 3, in which front cover 102 and rear cover 104 are pivoted towards each other and are in contact.

Referring to FIG. 2, in other configurations, the front cover 102 can pivot about first hinge 116 so that front cover exterior face 106 (as shown in FIG. 1) approaches the exterior face (not shown) of rear cover 104.

A second embodiment is shown in FIG. 4 as case 200. Case 200 includes a front cover 202, having a front cover interior face 208, and a rear cover 204, having a rear cover exterior face 218. Case 200 can also include openings 212a-212c, which are the same or similar to openings 112a-112g discussed above in regards to FIG. 1. Front cover 202 includes a filter material 214, which is the same or similar to filter material 114 discussed above.

Case 200 also includes a stand 220. Stand 220 is operably connected to rear cover exterior face 218 by a second hinge 222, so that stand 200 can be positioned to be along the rear cover exterior face 218, or stand 220 can be pivoted away rear cover exterior face 218, as shown in FIG. 4. Second hinge 222 can be any suitable mechanical feature that allows for front cover 202 and rear cover 204 to pivot in relation to each other.

In the configuration shown in FIG. 4, front cover 202 can be pivoted away from rear cover 204 when stand 220 is extended, but in other configurations, front cover 202 can be pivoted towards rear cover 204 when stand 220 is extended, so that front cover interior face 208 is in contact with rear cover interior face (not shown).

Stand 220 can also include an optional connector 224, which operably connects the bottom portion of stand 220 to a portion of the rear cover 204 that is a distance separate from where the second hinge 222 is placed. Each of stand 220, second hinge 222 and connector 224 can be formed of one or more materials that can maintain a predetermined shape, such as but not limited to, metals, plastics, woods, leathers, vinyls, textile based materials, paper based materials, synthetic and natural rubber materials, foam materials, and other polymers.

The described embodiments and examples of the present disclosure are intended to be illustrative rather than restrictive, and are not intended to represent every embodiment or example of the present disclosure. While the fundamental novel features of the disclosure as applied to various specific embodiments thereof have been shown, described and pointed out, it will also be understood that various omissions, substitutions and changes in the form and details of the devices illustrated and in their operation, may be made by those skilled in the art without departing from the spirit of the disclosure. For example, it is expressly intended that all combinations of those elements and/or method steps which perform substantially the same function in substantially the same way to achieve the same results are within the scope of the disclosure. Moreover, it should be recognized that structures and/or elements and/or method steps shown and/or described in connection with any disclosed form or embodiment of the disclosure may be incorporated in any other disclosed or described or suggested form or embodiment as a general matter of design choice. Further, various modifications and variations can be made without departing from the spirit or scope of the disclosure as set forth in the following claims both literally and in equivalents recognized in law.

1. A case for holding an electronic device, comprising:
a front cover;
a rear cover, wherein the front cover and rear cover are operably connected and are configured to form a cavity for placement of an electronic device, the electronic device comprising a display that is capable of creating a display image; and
a filter material forming at least one portion of the front cover, wherein the filter material provides a diminished image of the display image when the filter material is viewed at an angle between about 5° and about 35°, the angle being horizontally, vertically or a combination of horizontally and vertically from perpendicular to the filter material.

2. The case according to claim 1, wherein the filter material provides a diminished image of the display image when the filter material is viewed at an angle between about 30° and about 35°, the angle being horizontally, vertically or a combination of horizontally and vertically from perpendicular to the filter material.

3. (canceled)

4. The case according to claim 1, wherein the front cover and rear cover are operably connected about a hinge.

5. The case according to claim 1, further comprising a stand operable connected to the rear cover.

6. The case according to claim 1, wherein at least one of the front cover and the rear cover includes one or more openings.

7. The case according to claim 6, wherein the one or more openings provide access, operation, or access and operation of volume control, power control, a camera, a microphone, a headphone access, power inputs, video inputs and speakers of the electronic device.

8. The case according to claim 1, wherein the filter material forms two or more portions of the front cover.

9. The case according to claim 1, where the front cover and rear cover, independently of one another, comprise one or more metal materials, plastic materials, wood materials, leather materials, vinyl materials, textile based materials, paper based materials, synthetic rubber materials, natural rubber materials and foam materials.

10. The case according to claim 1 wherein the filter material provides a diminished image of the display image when the filter material is viewed at an angle between about 5° and about 30°.

11. The case according to claim 1 wherein the filter material provides a diminished image of the display image when the filter material is viewed at an angle between about 5° and about 25°.

12. The case according to claim 1 wherein the filter material provides a diminished image of the display image when the filter material is viewed at an angle between about 5° and about 20°.

13. The case according to claim 1 wherein the filter material provides a diminished image of the display image when the filter material is viewed at an angle between about 5° and about 15°.

14. The case according to claim 1 wherein the filter material provides a diminished image of the display image when the filter material is viewed at an angle between about 5° and about 10°.
